(19) United States
(12) Patent Application Publication
(10) Pub. No.: US 2007/0281429 A1
(43) Pub. Date: Dec. 6, 2007

(54) Method for fabricating semiconductor device

(76) Inventor: Yoshihiro Sato, Hyogo (JP)

Correspondence Address: MCDERMOTT WILL & EMERY LLP, 600 13TH STREET, NW, WASHINGTON, DC, 20005-3096, US

(21) Appl. No.: 11/730,805

(22) Filed: Apr. 4, 2007

(30) Foreign Application Priority Data
Apr. 13, 2006 (JP) 2006-111001

(51) Int. Cl. H01L 21/336

(52) U.S. Cl. 438/294; 257/E21.409

(57) ABSTRACT

In a method for fabricating a semiconductor device, a first region in a semiconductor substrate is formed with a first-gate-electrode formation portion composed of a first silicon film, a second silicon film, and a second protective film, and a second region therein is formed with a second-gate-electrode formation portion composed of the first silicon film, a first protective film, the second silicon film, and the second protective film. Then, the first-gate-electrode formation portion is formed into a first fully silicided gate electrode, and the second-gate-electrode formation portion is formed into a second fully silicided gate electrode.

### CROSS-REFERENCE TO RELATED APPLICATIONS

This application claims priority under 35 U.S.C. § 119 on Patent Application No. 2006-111001 filed in Japan on Apr. 13, 2006, the entire contents of which are hereby incorporated by reference.

### BACKGROUND OF THE INVENTION

(a) Fields of the Invention

The present invention relates to methods for fabricating a semiconductor device, and in particular to methods for fabricating a semiconductor device with fully silicided gate electrodes.

(b) Description of Related Art

With recent enhancement of packing density, functionality, and speed of a semiconductor integrated circuit device, a metal gate electrode thereof using a metal material is actively developed. Potential metal gate electrodes to be developed include: a dual metal gate electrode formed of a combination of two types of metal materials with different work functions; and a fully silicided (FUSI) gate electrode the whole of which is formed of metal silicide. In particular, the FUSI gate electrode can be formed by following a currently-used silicon process technology, so that it receives attention as a promising technology.

The FUSI gate electrode can be formed so that a gate polysilicon film is formed in much the same manner as formation of a typical polysilicon gate and then the formed film is allowed to react with metal such as nickel.

However, only replacement of a polysilicon gate electrode of a transistor with a FUSI gate electrode will rather cause a change in the threshold voltage of the transistor due to the work functions of the gate electrodes. This makes it difficult for each of a p-channel MIS (metal-insulator-semiconductor) transistor and an n-channel MIS transistor to secure a predetermined threshold voltage.

To solve this problem, an attempt to change the silicide composition of the FUSI gate electrode is being made. By changing the silicide composition of the FUSI gate electrode, the work function of the gate electrode can also change to control the threshold voltage.

The silicide composition of the FUSI gate electrode is determined by the thickness of a polysilicon film before full silicidation. Based on this characteristic, a method is developed in which after deposition of a polysilicon film, the thickness of the film is adjusted by etching and then the adjusted film is fully silicided to control the threshold voltage (see, for example, Japanese Unexamined Patent Publication No. 2005-228868 and A. Lauwers et al., “CMOS Integration of Dual Work Function Phase Controlled Ni FUSI with Simultaneous Silicidation of NMOS (NiSi) and PMOS (Ni-rich silicide) Gates on HfSiON”, IEDM2005).

The conventional method for forming a fully silicided gate electrode, however, has a problem that since the thickness of the polysilicon film is adjusted by etching, the adjusted film thickness widely varies.

In order to accurately adjust the film thickness by etching, it is necessary to precisely control the etching rate and the etching time. However, since the etching rate varies widely with the formation process, thickness variation between substrates occurs. This leads to a wide range of lot-to-lot variation in threshold voltage.

The etching rate also varies with the etching area. Thus, a transistor having a gate electrode with a large area and a transistor having a gate electrode with a small area differ in the etched polysilicon film thickness. As a result, variation in silicide composition occurs even between the transistors within the substrate. This leads to variation in threshold voltage and gate resistance.

Even within the same gate electrode, depending on the roughness of the surface of the etched polysilicon film, there disadvantageously occurs a portion with a different silicide composition.

### SUMMARY OF THE INVENTION

An object of the present invention is to solve the conventional problems described above, and to provide a method for fabricating a semiconductor device capable of accurately forming a fully silicided gate electrode with a predetermined silicide composition.

To attain the above object, in the present invention, a method for fabricating a semiconductor device is carried out so that the silicon film thickness in the device is adjusted by depositing a silicon film twice.

To be more specific, a method for fabricating a semiconductor device according to the present invention is characterized in that the method includes: the step (a) of forming, in a semiconductor substrate, a first region and a second region separated from each other by an isolation region; the step (b) of forming a first-gate-electrode formation portion above the first region and a second-gate-electrode formation portion above the second region, the first-gate-electrode formation portion being composed, in this order, of a first silicon film, a second silicon film, and a second protective film, the second-gate-electrode formation portion being composed, in this order, of the first silicon film, a first protective film, the second silicon film, and the second protective film; the step (c) of removing the second protective film of the first-gate-electrode formation portion to expose the second silicon film, and removing the second protective film, the second silicon film, and the first protective film of the second-gate-electrode formation portion to expose the first silicon film; and the step (d) of forming, after the step (c), a metal film over the semiconductor substrate, and then performing a thermal treatment for silicidation of the first and second silicon films of the first-gate-electrode formation portion, thereby forming a first fully silicided gate electrode, and for silicidation of the first silicon film of the second-gate-electrode formation portion, thereby forming a second fully silicided gate electrode.

With the method for fabricating a semiconductor device according to the present invention, in the second-gate-electrode formation portion, only the second silicon film can be selectively removed therefrom, and full silicidation is conducted on the first silicon film. On the other hand, in the first-gate-electrode formation portion, full silicidation is conducted on the first and second silicon films. Therefore, two types of fully silicided gate electrodes having different silicide compositions can be formed with a good repeatability.

Preferably, in the method for fabricating a semiconductor device according to the present invention, the step (b) includes: the step (b1) of sequentially forming the first silicon film and the first protective film over the semiconductor substrate; the step (b2) of removing a portion of the first protective film located over the first region, and then forming the second silicon film and the second protective film over the semiconductor substrate; and the step (b3) of patterning portions of the first silicon film, the second silicon film, and the second protective film located over the first region to form the first-gate-electrode formation portion, and patterning portions of the first silicon film, the first protective film, the second silicon film, and the second protective film located over the second region to form the second-gate-electrode formation portion. With this method, the first-gate-electrode formation portion and the second-gate-electrode formation portion can be formed efficiently.

Preferably, in the above case, the step (b1) includes the step of forming a gate-insulating-film formation film on the semiconductor substrate, and then sequentially forming the first silicon film and the first protective film on the gate-insulating-film formation film, and the step (b3) includes the step of patterning the gate-insulating-film formation film to form a first gate insulating film between the first region and the first-gate-electrode formation portion and a second gate insulating film between the second region and the second-gate-electrode formation portion.

Preferably, in the method for fabricating a semiconductor device according to the present invention, the gate-insulating-film formation film is a high dielectric constant film with a relative dielectric constant of 10 or higher.

Preferably, in the method for fabricating a semiconductor device according to the present invention, the gate-insulating-film formation film is a film containing metal oxide.

Preferably, in the method for fabricating a semiconductor device according to the present invention, the step (c) includes: the step (c1) of removing the second protective film of the second-gate-electrode formation portion to expose the second silicon film, and contrarily allowing the second protective film of the first-gate-electrode formation portion to remain so that exposure of the second silicon film is prevented; the step (c2) of selectively removing the second silicon film of the second-gate-electrode formation portion to expose the first protective film; and the step (c3) of selectively etching, after the step (c2), the second protective film of the first-gate-electrode formation portion to expose the second silicon film of the first-gate-electrode formation portion, and also selectively etching the first protective film of the second-gate-electrode formation portion to expose the first silicon film of the second-gate-electrode formation portion. With this method, in the first-gate-electrode formation portion, the first protective film can be used as an etching mask. Therefore, the second silicon film can be reliably removed only in the second-gate-electrode formation portion.

Preferably, in the above case, the step (c1) is the step of forming, over the first region, a mask film covering the first-gate-electrode formation portion, and then selectively removing, using the mask film as an etching mask, the second protective film of the second-gate-electrode formation portion to expose the second silicon film. With this method, the second protective film can be allowed to remain reliably in the first-gate-electrode formation portion, so that etching of the second silicon film can be reliably blocked in the first-gate-electrode formation portion.

In the step (c1), removal of the second protective film of the second-gate-electrode formation portion may be conducted either by etching or by a chemical mechanical polishing method.

Preferably, in the method for fabricating a semiconductor device according to the present invention, the step (c) includes: the step (c1) of removing the second protective film of the first-gate-electrode formation portion to expose the second silicon film, and removing the second protective film of the second-gate-electrode formation portion to expose the second silicon film; the step (c2) of forming, after the step (c1), a mask film over the first region, the mask film covering the second silicon film of the first-gate-electrode formation portion; and the step (c3) of selectively etching, using the mask film as an etching mask, the second silicon film and the first protective film of the second-gate-electrode formation portion to expose the first silicon film. With this method, the first protective film does not have to be allowed to remain in the first-gate-electrode formation portion. Therefore, the first-protective-film etching step can be simplified.

In the above case, in the step (c1), removal of the respective second protective films may be conducted either by etching or by a chemical mechanical polishing method.

Preferably, the method for fabricating a semiconductor device according to the present invention further includes, between the steps (b) and (c), the step (e) of performing, using the first-gate-electrode formation portion and the second-gate-electrode formation portion as a mask, ion implantation on the first region and the second region to form first source/drain regions in areas of the first region and the second region located below both sides of the first-gate-electrode formation portion and the second-gate-electrode formation portion, respectively, the step (f) of forming, after the step (e), insulating side walls on side surfaces of the first-gate-electrode formation portion and the second-gate-electrode formation portion, respectively, and the step (g) of performing, using the sidewalls as a mask, ion implantation on the first region and the second region to form second source/drain regions in areas of the first region and the second region located outside the sidewalls, respectively.

Preferably, the method for fabricating a semiconductor device according to the present invention further includes, between the steps (g) and (c), the step (h) of forming, over the semiconductor substrate, an interlayer insulating film covering the first-gate-electrode formation portion and the second-gate-electrode formation portion.

Preferably, in the method for fabricating a semiconductor device according to the present invention, the silicon film is a polysilicon film or an amorphous silicon film.

Preferably, in the method for fabricating a semiconductor device according to the present invention, the first and second protective films are silicon oxide film, respectively.

Preferably, in the method for fabricating a semiconductor device according to the present invention, the metal film is made of transition metal.

Preferably, in the method for fabricating a semiconductor device, the metal film contains at least one of nickel, cobalt, platinum, titanium, ruthenium, iridium, and ytterbium.

### BRIEF DESCRIPTION OF THE DRAWINGS

FIGS. 1A to 1F are sectional views showing a method for fabricating a semiconductor device according to one embodiment of the present invention in the order of its fabrication process steps.

FIGS. 2A to 2F are sectional views showing the method for fabricating a semiconductor device according to one embodiment of the present invention in the order of its fabrication process steps.

FIGS. 3A to 3D are sectional views showing the method for fabricating a semiconductor device according to one embodiment of the present invention in the order of its fabrication process steps.

FIGS. 4A to 4D are sectional views showing another example of the method for fabricating a semiconductor device according to one embodiment of the present invention in the order of its fabrication process steps.

### BEST MODE FOR CARRYING OUT THE INVENTION

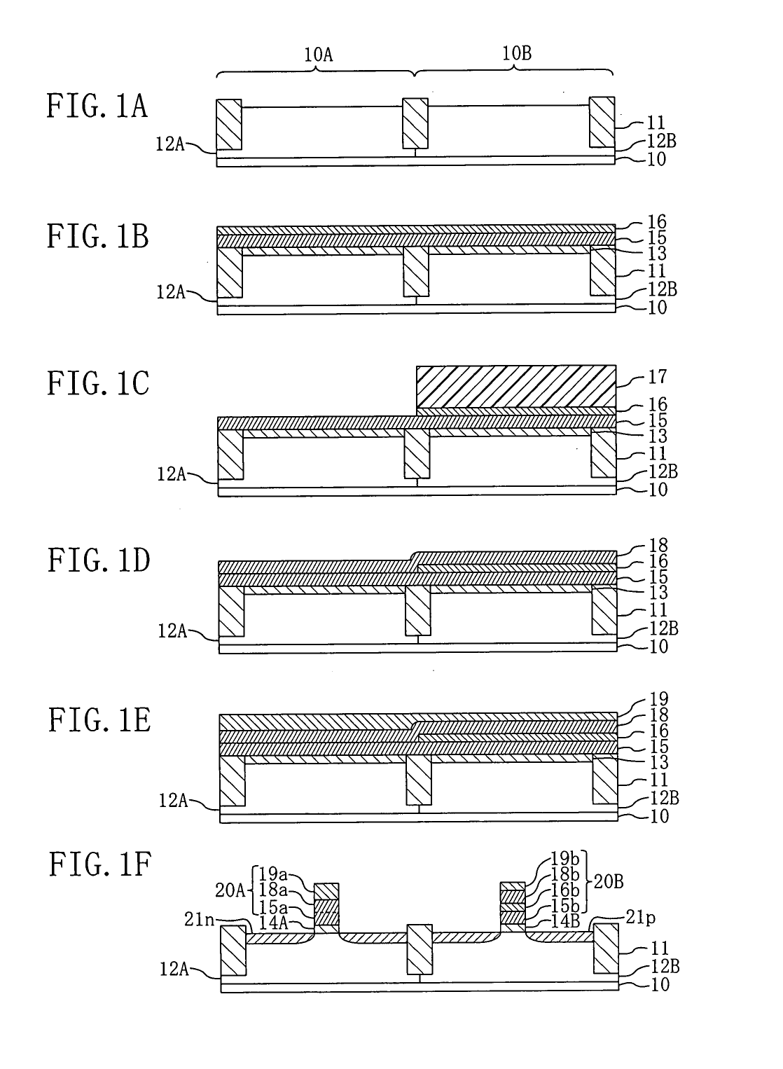

One embodiment of the present invention will be described with reference to the accompanying drawings. FIGS. 1 to 3 show cross-sectional structures of successive fabrication process steps of a method for fabricating a semiconductor device according to one embodiment. In this embodiment, description will be made of a method for fabricating n- and p-type MIS transistors in first and second regions 10A and 10B, respectively.

Referring to FIG. 1A, first, on a semiconductor substrate 10 made of, for example, p-type silicon, an isolation region 11 for electrically isolating elements is provided by an STI (shallow trench isolation) method or the like to form the first region 10A and the second region 10B. Then, by a lithography method and an ion implantation method, a p-type first well 12A and an n-type second well 12B are formed in the upper portion of the first region 10A and the second region 10B, respectively.

Next, as shown in FIG. 1B, in a region of the main surface of the semiconductor substrate 10 surrounded with the isolation region 11, a 2 nm-thick gate-insulating-film formation film 13 of silicon oxide is formed by a dry oxidation method or a wet oxidation method, or with radical oxygen or the like. Then, on the isolation region 11 and the gate-insulating-film formation film 13, a 40 nm-thick first silicon film 15 of polysilicon serving as a gate electrode is formed by a CVD (chemical vapor deposition) method or the like. On the first polysilicon film, a 30 nm-thick first protective film 16 of silicon oxide is formed by a CVD method or the like.

Subsequently, as shown in FIG. 1C, by a photolithography method, a photoresist pattern 17 is formed which covers the second region 10B and exposes the first region 10A, and then dry etching is performed to remove a portion of the first protective film 16 formed in the first region 10A.

As shown in FIG. 1D, the photoresist pattern 17 is removed. Then, on the first and second regions 10A and 10B, a 60 nm-thick second silicon film 18 of polysilicon serving as a gate electrode is deposited by a CVD method or the like.

Next, as shown in FIG. 1E, on the second silicon film 18, a second protective film 19 of silicon oxide is formed by a CVD method or the like. By a chemical mechanical polishing (CMP) method, the surface of the second protective film 19 is planarized to form a portion of the second protective film 19 lying in the first region 10A to have a thickness of 60 nm, and a portion thereof lying in the second region 10B to have a thickness of 30 nm.

Subsequently, as shown in FIG. 1F, by a photolithography method and a dry etching method, the gate-insulating-film formation film 13, the first silicon film 15, the first protective film 16, the second silicon film 18, and the second protective film 19 are selectively etched. Thereby, the first region 10A is formed with: a first-gate-electrode formation portion 20A composed of the patterned first silicon film 15a, second silicon film 18a, and second protective film 19a; and a first gate insulating film 14A composed of the patterned gate-insulating-film formation film 13. On the other hand, the second region 10B is formed with: a second-gate-electrode formation portion 20B composed of the patterned first silicon film 15b, first protective film 16b, second silicon film 18b, and second protective film 19b; and a second gate insulating film 14B composed of the patterned gate-insulating-film formation film 13.

Next, using the first-gate-electrode formation portion 20A as a mask, ion implantation with an n-type impurity is performed to form first n-type source/drain diffusion layers 21n, which serve as shallow source/drain diffusion layers, in areas of the first region 10A located on both sides of the first-gate-electrode formation portion 20A, respectively. Likewise, using the second-gate-electrode formation portion 20B as a mask, ion implantation with a p-type impurity is performed to form first p-type source/drain diffusion layers 21p, which serve as shallow source/drain diffusion layers, in areas of the second region 10B located on both sides of the second-gate-electrode formation portion 20B, respectively.

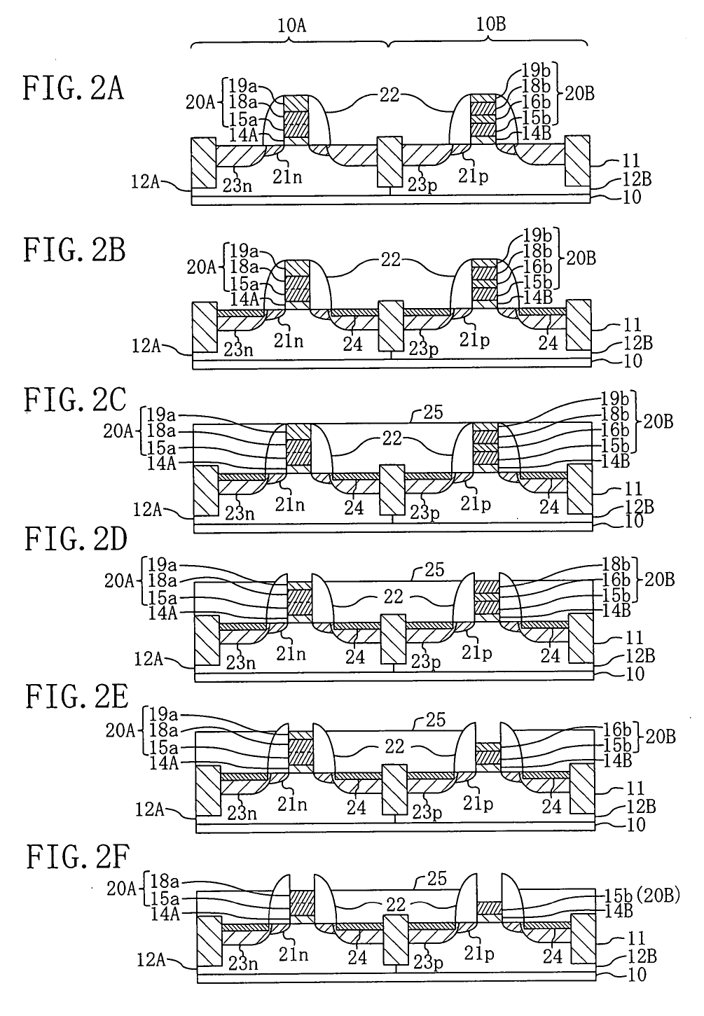

As shown in FIG. 2A, over the entire surface of the semiconductor substrate 10, for example, a 50 nm-thick silicon nitride film is deposited by a CVD method or the like. Then, the deposited silicon nitride film is anisotropically etched to remove the silicon nitride film other than portions thereof located on the side surfaces of the first-gate-electrode formation portion 20A and the second-gate-electrode formation portion 20B. Thereby, sidewalls 22 are formed on the side surfaces of the first-gate-electrode formation portion 20A and the second-gate-electrode formation portion 20B, respectively.

Next, using the first-gate-electrode formation portion 20A and the sidewall 22 as a mask, ion implantation with an n-type impurity is performed to form, in areas of the first region 10A located outside the sidewalls 22, second n-type source/drain diffusion layers 23n serving as deep source/drain diffusion layers, respectively. Likewise, using the second-gate-electrode formation portion 20B and the sidewall 22 as a mask, ion implantation with a p-type impurity is performed to form, in areas of the second region 10B located outside the sidewalls 22, second p-type source/drain diffusion layers 23p serving as deep source/drain diffusion layers, respectively.

Subsequently, as shown in FIG. 2B, a native oxide film is removed from the surfaces of the second n-type and p-type source/drain diffusion layers 23n and 23p, and then by a sputtering method or the like, an 11 nm-thick metal film (not shown) of nickel is deposited over the semiconductor substrate 10. Thereafter, in a nitrogen atmosphere, the semiconductor substrate 10 is subjected to a first RTA (rapid thermal annealing) at 320° C., whereby silicon is allowed to react with the metal film to form the surfaces of the second n-type and p-type source/drain diffusion layers 23n and 23p into nickel silicide. The resulting semiconductor substrate 10 is immersed in an etching solution made of a mixed acid of hydrochloric acid, hydrogen peroxide solution, and the like to remove an unreacted metal film remaining on the isolation region 11, the first-gate-electrode formation portion 20A, the second-gate-electrode formation portion 20B, the sidewalls 22, and the like. Thereafter, the semiconductor substrate 10 is subjected to a second RTA at a higher temperature (for example, 550° C.) than that of the first RTA. Thereby, the surfaces of the second n-type and p-type source/drain diffusion layers 23n and 23p are each formed with a silicide layer 24 with a low resistance.

As shown in FIG. 2C, an interlayer insulating film 25 made of, for example, a silicon oxide film is formed over the semiconductor substrate 10. Subsequently, while a CMP method is carried out to planarize the surface of the interlayer insulating film 25, the polishing is performed until the top surfaces of the first-gate-electrode formation portion 20A and the second-gate-electrode formation portion 20B are exposed.

Next, as shown in FIG. 2D, by a dry etching method or a wet etching method having an etching condition set to provide a high selectivity with respect to a silicon nitride film, the second protective film 19a contained in the first-gate-electrode formation portion 20A and the second protective film 19b contained in the second-gate-electrode formation portion 20B are etched to expose the top surface of the second silicon film 18b contained in the second-gate-electrode formation portion 20B. During this etching, the second protective film 19a contained in the first-gate-electrode formation portion 20A is allowed to remain so that exposure of the second silicon film 18a is prevented. Note that etching of the surface of the interlayer insulating film 25 by this etching causes no special trouble.

Subsequently, as shown in FIG. 2E, by a dry etching method having an etching condition set to provide high selectivities with respect to a silicon oxide film and a silicon nitride film, the second silicon film 18b is removed from the second-gate-electrode formation portion 20B to expose the first protective film 16b.

As shown in FIG. 2F, by a dry etching method or a wet etching method having an etching condition set to provide high selectivities with respect to a silicon nitride film and a polysilicon film, the second protective film 19a is removed from the first-gate-electrode formation portion 20A to expose the second silicon film 18a, and also the first protective film 16b is removed from the second-gate-electrode-formation portion 20B to expose the first silicon film 15b.

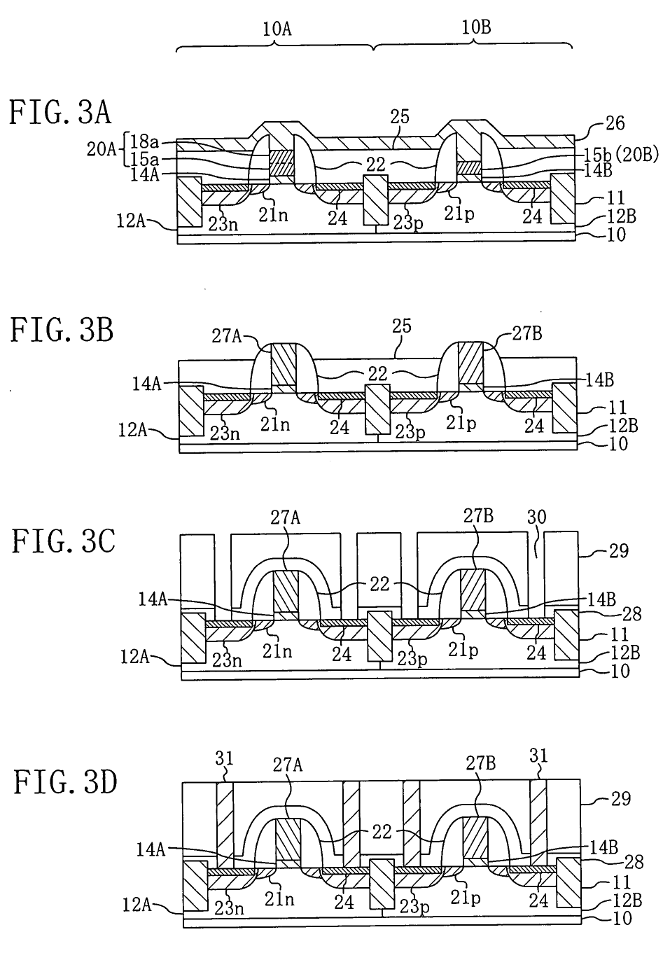

Next, as shown in FIG. 3A, on the interlayer insulating film 25, a 70 nm-thick metal film 26 of nickel covering the first-gate-electrode formation portion 20A and the second-gate-electrode formation portion 20B is deposited by, for example, a sputtering method. Then, in a nitrogen atmosphere, the semiconductor substrate 10 is subjected to an RTA at 380° C., whereby the first and second silicon films 15a and 18a of the first-gate-electrode formation portion 20A and the first silicon film 15b of the second-gate-electrode formation portion 20B are allowed to react with the metal film 26 to perform full silicidation on the first and second silicon films 15a and 18a of the first-gate-electrode formation portion 20A and on the first silicon film 15b of the second-gate-electrode formation portion 20B.

In the manner described above, as shown in FIG. 3B, the first region 10A is formed with a first FUSI gate electrode 27A having a silicide composition made of NiSi, and also the second region 10B is formed with a second FUSI gate electrode 27B having a silicide composition made of Ni₃Si or Ni₂Si.

Subsequently, as shown in FIG. 3C, the interlayer insulating film 25 is removed, and then over the semiconductor substrate 10, an underlayer protective film made of a 20 nm-thick silicon nitride film 28 is deposited by a CVD method or the like. On the deposited silicon nitride film 28, an interlayer insulating film 29 made of a silicon oxide film is formed by a CVD method or the like. Thereafter, a photoresist mask pattern (not shown) is formed on the interlayer insulating film 29, and by a dry etching method, a contact hole 30 is formed which exposes the silicide layer 24 provided on the source/drain diffusion layer. During this etching, a two-step etching method in which the etching is temporarily stopped at the instant of exposure of the silicon nitride film 28 can be employed to reduce the amount of overetching of the silicide layer 24.

As shown in FIG. 3D, titanium nitride and titanium serving as a barrier metal film for tungsten are sequentially deposited by a sputtering method or a CVD method, and subsequently tungsten is deposited by a CVD method. Thereafter, the deposited tungsten is subjected to CMP to remove tungsten deposited on the interlayer insulating film 29 located outside the contact hole 30. Thus, a contact plug 31 is formed.

As described above, with the method for fabricating a semiconductor device according to this embodiment, the first-gate-electrode formation portion and the second-gate-electrode formation portion are formed by depositing silicon films multiple times. In addition, in the second-gate-electrode formation portion, the protective film is provided between the silicon films. With such a structure, the upper-layer silicon film can be selectively removed from the second-gate-electrode formation portion. Therefore, the silicon film of the first-gate-electrode formation portion and the silicon film of the second-gate-electrode formation portion can easily have different thicknesses. Moreover, since the thickness of the silicon film of the first-gate-electrode formation portion and the thickness of the silicon film of the second-gate-electrode formation portion are both controlled by deposition, variations in the thicknesses can be reduced to a small range. As a result, even in the case where transistors with different gate areas are present, variation in the silicide composition can be reduced to a small range.

Furthermore, when the film thickness is adjusted by etching, the difference in etching rate occurs even within the same gate electrode. Because of this difference, the edge portion and the center portion of the formed gate electrode differ in thickness, which causes a problem that a portion with a different silicide composition is likely to be formed locally within the gate electrode. However, in this embodiment, the film thickness is adjusted by deposition. Therefore, the film having a flat surface with a small roughness can be provided to improve the uniformity of the silicide composition within the gate electrode.

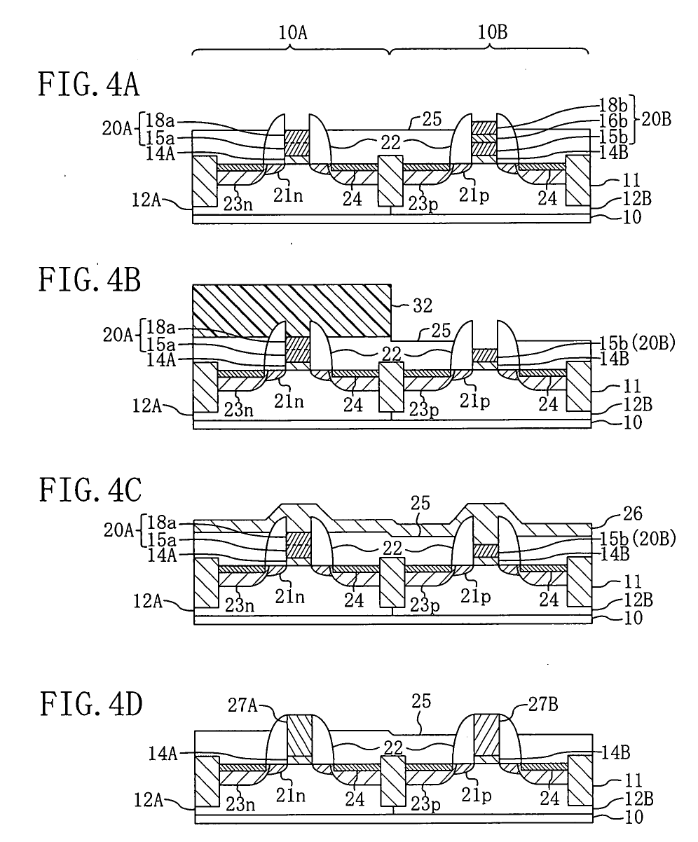

In this embodiment, the exemplary method has been shown in which the second protective film 19a of the first-gate-electrode formation portion 20A is allowed to remain as a mask for etching the second silicon film 18b of the second-gate-electrode formation portion 20B. Alternatively, as shown in FIG. 4A, the second protective film 19a of the first-gate-electrode formation portion 20A may be removed together with the second protective film 19b of the second-gate-electrode formation portion 20B.

In this case, it is sufficient that, as shown in FIG. 4B, after formation of a mask 32 of a photoresist or the like covering the first region 10A, etching is performed on the second silicon film 18b and the first protective film 16b of the second-gate-electrode formation portion 20B. Subsequently to this, as shown in FIGS. 4C and 4D, after removal of the mask 32, silicidation is performed on the first and second silicon films 15a and 18a of the first-gate-electrode formation portion 20A and the first silicon film 15b of the second-gate-electrode formation portion 20B, thereby forming the first FUSI gate electrode 27A and the second FUSI gate electrode 27B. Although in this case, the process for forming the mask 32 is required, this case also has an advantage that the necessity to precisely control the etching time for the purpose of allowing the second protective film 19a to remain is eliminated.

Another approach may be employed in which the mask 32 covering the first region 10A is first formed, the second protective film 19b and the second silicon film 18b of the second-gate-electrode formation portion 20B are removed, and etching is performed on the second protective film 19a of the first-gate-electrode formation portion 20A and the first protective film 16b of the second-gate-electrode formation portion 20B.

The second protective films 19a and 19b may be removed by a CMP method until the top surface of the second silicon film 18b is exposed. Although in this case, a portion of the sidewall 22 is also polished, this case also has an advantage that the number of etching process steps can be reduced.

In this embodiment, the first and second gate insulating films 14A and 14B are formed of silicon oxide. Instead of this, a high dielectric film may be used. By thus using a high dielectric film, Fermi level pinning can be released to control the threshold voltage. As the high dielectric film, use can be made of a film of hafnium-based oxide, such as a hafnium dioxide (HfO₂) film, a hafnium silicate (HfSiO) film, or a nitrided hafnium silicate (HfSiON) film. Other than these films, a high dielectric film made of a material containing at least one of zirconium (Zr), titanium (Ti), tantalum (Ta), aluminum (Al), rare-earth metal including scandium (Sc), yttrium (Y), lanthanum (La), and other lanthanoids, and the like. In particular, a film with a relative dielectric constant of 10 or higher is preferably used.

In this embodiment, the first and second silicon films 15 and 18 are formed of polysilicon. Instead of this, they may be formed of another semiconductor material and the like including amorphous silicon or silicon.

As a metal for forming the silicide layer 24, nickel is used. Instead of this, for example, metal for silicidation such as cobalt, titanium, and tungsten may be used.

As a metal for forming the first and second FUSI gate electrodes 27A and 27B, nickel is used. Instead of this, transition metal such as platinum, cobalt, titanium, ruthenium, iridium, and ytterbium may be used as a FUSI metal.

The sidewall 22 is formed of a silicon nitride film. Alternatively, it may be formed by stacking a silicon oxide film and a silicon nitride film.

It is sufficient that the silicon nitride film 28 is formed as required. If the silicon nitride film 28 is not formed, the interlayer insulating film 29 may be deposited, without etching the interlayer insulating film 25, on the interlayer insulating film 25. Alternatively, deposition of the silicon nitride film 28 may be performed before deposition of the interlayer insulating film 25. In this case, it is sufficient that in exposing the first-gate-electrode formation portion 20A and the second-gate-electrode formation portion 20B by polishing the interlayer insulating film 25 by a CMP method, portions of the silicon nitride film 28 deposited on top of the first-gate-electrode formation portion 20A and the second-gate-electrode formation portion 20B are removed.

As described above, with the method for fabricating a semiconductor device according to the present invention, a method for fabricating a semiconductor device capable of accurately forming a fully silicided gate electrode with a predetermined silicide composition can be provided. Accordingly, the present invention is useful for, for example, a method for fabricating a semiconductor device with fully silicided gate electrodes.

What is claimed is:

1. A method for fabricating a semiconductor device, comprising:
the step (a) of forming, in a semiconductor substrate, a first region and a second region separated from each other by an isolation region;
the step (b) of forming a first-gate-electrode formation portion above the first region and a second-gate-electrode formation portion above the second region, the first-gate-electrode formation portion being composed, in this order, of a first silicon film, a second silicon film, and a second protective film, the second-gate-electrode formation portion being composed, in this order, of the first silicon film, a first protective film, the second silicon film, and the second protective film;
the step (c) of removing the second protective film of the first-gate-electrode formation portion to expose the second silicon film, and removing the second protective film, the second silicon film, and the first protective film of the second-gate-electrode formation portion to expose the first silicon film; and
the step (d) of forming, after the step (c), a metal film over the semiconductor substrate, and then performing a thermal treatment for silicidation of the first and second silicon films of the first-gate-electrode formation portion, thereby forming a first fully silicided gate electrode, and for silicidation of the first silicon film of the second-gate-electrode formation portion, thereby forming a second fully silicided gate electrode.

2. The method of claim 1,
wherein the step (b) includes:
the step (b1) of sequentially forming the first silicon film and the first protective film over the semiconductor substrate;
the step (b2) of removing a portion of the first protective film located over the first region, and then forming the second silicon film and the second protective film over the semiconductor substrate; and
the step (b3) of patterning portions of the first silicon film, the second silicon film, and the second protective film located over the first region to form the first-gate-electrode formation portion, and patterning portions of the first silicon film, the first protective film, the second silicon film, and the second protective film located over the second region to form the second-gate-electrode formation portion.

3. The method of claim 2,
wherein the step (b1) includes the step of forming a gate-insulating-film formation film on the semiconductor substrate, and then sequentially forming the first silicon film and the first protective film on the gate-insulating-film formation film, and
the step (b3) includes the step of patterning the gate-insulating-film formation film to form a first gate insulating film between the first region and the first-gate-electrode formation portion and a second gate insulating film between the second region and the second-gate-electrode formation portion.

4. The method of claim 3,
wherein the gate-insulating-film formation film is a high dielectric constant film with a relative dielectric constant of 10 or higher.

5. The method of claim 3,
wherein the gate-insulating-film formation film is a film containing metal oxide.

6. The method of claim 1,
wherein the step (c) includes:
the step (c1) of removing the second protective film of the second-gate-electrode formation portion to expose the second silicon film, and contrarily allowing the second protective film of the first-gate-electrode formation portion to remain so that exposure of the second silicon film is prevented;
the step (c2) of selectively removing the second silicon film of the second-gate-electrode formation portion to expose the first protective film; and
the step (c3) of selectively etching, after the step (c2), the second protective film of the first-gate-electrode formation portion to expose the second silicon film of the first-gate-electrode formation portion, and also selectively etching the first protective film of the second-gate-electrode formation portion to expose the first silicon film of the second-gate-electrode formation portion.

7. The method of claim 6,
wherein the step (c1) is the step of forming, over the first region, a mask film covering the first-gate-electrode formation portion, and then selectively removing, using the mask film as an etching mask, the second protective film of the second-gate-electrode formation portion to expose the second silicon film.

8. The method of claim 6,
wherein in the step (c1), removal of the second protective film of the second-gate-electrode formation portion is conducted by etching.

9. The method of claim 6,
wherein in the step (c1), removal of the second protective film of the second-gate-electrode formation portion is conducted by a chemical mechanical polishing method.

10. The method of claim 1,
wherein the step (c) includes:
the step (c1) of removing the second protective film of the first-gate-electrode formation portion to expose the second silicon film, and removing the second protective film of the second-gate-electrode formation portion to expose the second silicon film;
the step (c2) of forming, after the step (c1), a mask film over the first region, the mask film covering the second silicon film of the first-gate-electrode formation portion; and
the step (c3) of selectively etching, using the mask film as an etching mask, the second silicon film and the first protective film of the second-gate-electrode formation portion to expose the first silicon film.

11. The method of claim 10,
wherein in the step (c1), removal of the respective second protective films is conducted by etching.

12. The method of claim 10,
wherein in the step (c1), removal of the respective second protective films is conducted by a chemical mechanical polishing method.

13. The method of claim 1, further comprising, between the steps (b) and (c),
the step (e) of performing, using the first-gate-electrode formation portion and the second-gate-electrode formation portion as a mask, ion implantation on the first region and the second region to form first source/drain regions in areas of the first region and the second region located below both sides of the first-gate-electrode formation portion and the second-gate-electrode formation portion, respectively,
the step (f) of forming, after the step (e), insulating side walls on side surfaces of the first-gate-electrode formation portion and the second-gate-electrode formation portion, respectively, and
the step (g) of performing, using the sidewalls as a mask, ion implantation on the first region and the second region to form second source/drain regions in areas of the first region and the second region located outside the sidewalls, respectively.

14. The method of claim 13, further comprising, between the steps (g) and (c), the step (h) of forming, over the semiconductor substrate, an interlayer insulating film covering the first-gate-electrode formation portion and the second-gate-electrode formation portion.

15. The method of claim 1,
wherein the silicon film is a polysilicon film or an amorphous silicon film.

16. The method of claim 1,
wherein the first and second protective films are silicon oxide films, respectively.

17. The method of claim 1,
wherein the metal film is made of transition metal.

18. The method of claim 1,
wherein the metal film contains at least one of nickel, cobalt, platinum, titanium, ruthenium, iridium, and ytterbium.
